(19) United States
(12) Patent Application Publication
(10) Pub. No.: US 2016/0081208 A1
(43) Pub. Date: Mar. 17, 2016

(54) DISPLAY APPARATUS WITH MULTIPLE MEANS OF SUPPORT

(71) Applicants: HONG FU JIN PRECISION INDUSTRY (ShenZhen) CO., LTD, Shenzhen (CN); HON HAI PRECISION INDUSTRY CO., LTD., New Taipei (TW)

(72) Inventors: WEI-FANG DAI, Shenzhen (CN); KUANG-LUNG LIN, New Taipei (TW); CHING-HUA TSAI, New Taipei (TW); JEN-HUI OH, New Taipei (TW)

(21) Appl. No.: 14/790,345

(22) Filed: Jul. 2, 2015

(30) Foreign Application Priority Data
Sep. 15, 2014 (CN) 201410467624.4

(51) Int. Cl. H05K 5/02

(52) U.S. Cl. CPC H05K 5/0204; H05K 5/0234; H05K 5/0226

(57) ABSTRACT

A display apparatus can be placed in different orientations. The display apparatus includes a frame, a display panel received in the frame, a casing, a fixing portion, and at least one movable leg. The casing is mounted on the frame via a fixing portion. The frame and casing are pivotal relative one another between a first display orientation and a second display orientation. The at least movable leg changes from a first position on the frame when the frame and casing are in the first display orientation to a second position to cooperate with the casing and frame to place the frame and casing in the second display orientation.

### CROSS-REFERENCE TO RELATED APPLICATIONS

This application claims priority to Chinese Patent Application No. 201410467624.4 filed on Sep. 15, 2014, the contents of which are incorporated by reference herein.

### FIELD

The subject matter herein generally relates to a display apparatus.

### BACKGROUND

A display apparatus is capable of hanging on the wall or being supported on the table. A locating mechanism is needed to satisfy different types of location.

### BRIEF DESCRIPTION OF THE FIGURES

Implementations of the present technology will now be described, by way of example only, with reference to the attached figures.

FIG. 1 is an isometric view of an embodiment of the display apparatus in a first placing orientation.

FIG. 2 is exploded, isometric view of an embodiment of the display apparatus of FIG. 1 viewed from another angle.

FIG. 3 is an isometric view of an embodiment of the display apparatus of FIG. 1 viewed from another angle.

FIG. 4 is an isometric view of an embodiment of the display apparatus of FIG. 3 in a second placing orientation.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

The term “substantially” is defined to be essentially conforming to the particular dimension, shape or other feature that the term modifies, such that the component need not be exact. For example, “substantially cylindrical” means that the object resembles a cylinder, but can have one or more deviations from a true cylinder. The term “comprising” means “including, but not necessarily limited to”; it specifically indicates open-ended inclusion or membership in a so-described combination, group, series and the like.

The present disclosure is described in relation to a display apparatus which is adjustable in respect of an orientation of placement.

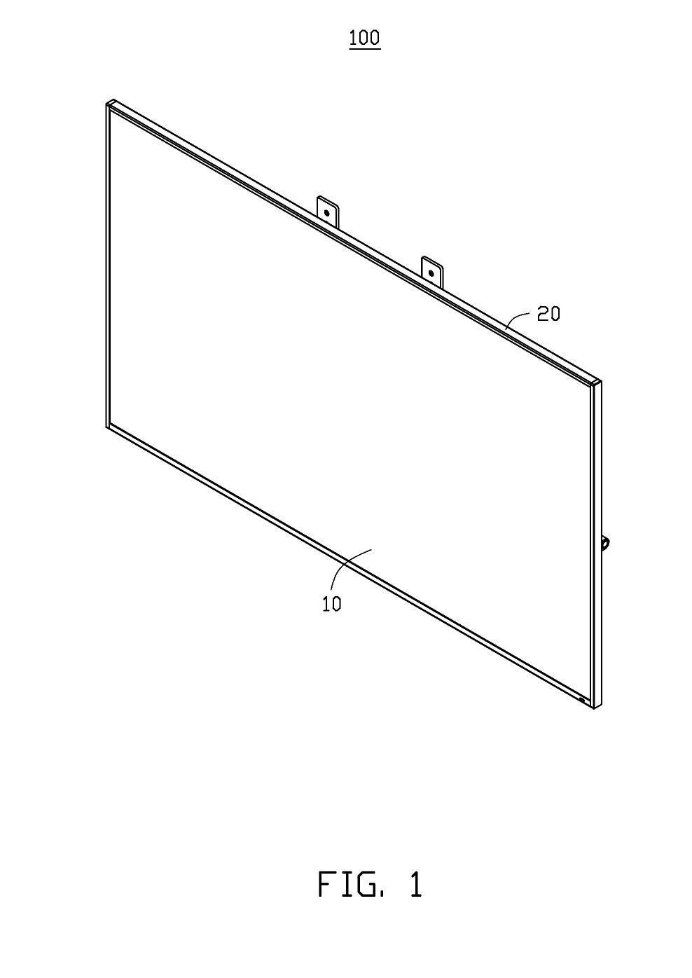

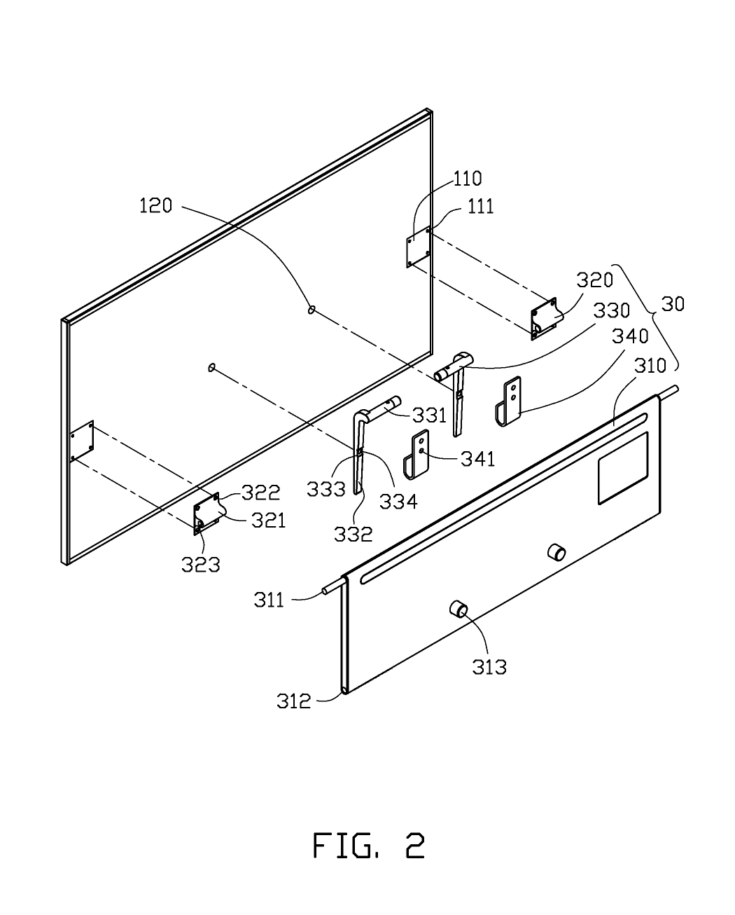

FIGS. 1-2 illustrate an embodiment of the display apparatus 100. The display apparatus 100 can be placed in different orientations. The display apparatus 100 includes a frame 10, a display panel 20 received in the frame 10, and a location mechanism 30 mounted on a back surface of the frame 10 away from the display panel 20. The display panel 20 displays images. The location mechanism 30 can support and locate the display apparatus 100 on a structure, such as a wall or a table. In at least embodiment, the display apparatus 100 is a television.

The frame 10 includes two positioning portions 110. The positioning portions 110 are located on the back surface of the frame 10, and symmetrical around a vertical midline of the frame 10. The positioning portions 110 cooperate with the location mechanism 30 to locate the location mechanism 30 on the frame 10. The positioning portion 110 is substantially plate shaped. The positioning portion 110 defines a plurality of receiving portions 111. The receiving portions 111 form a rectangle. The frame 10 further defines two first openings 120. The first openings 120 cooperate with the location mechanism 30. The first openings 120 are arranged in a line parallel with a line connecting the positioning portions 110 along a length of the frame 10.

The location mechanism 30 is capable of cooperating with the first opening 120 to allow the display apparatus 100 to be hung on a wall or to allow the frame 10 to support the display apparatus 100 on a table. The location mechanism 30 includes a casing 310, two fixing portions 320, and two movable legs 330, and a hook portion 340.

The casing 310 is substantially rectangular. The casing 310 includes two shafts 311 mounted on opposite side surfaces of the casing 310 and two supporting poles 313. An axis of each of the shafts 213 is perpendicular to the side surface of the casing 310. The supporting poles 313 are located on a surface of the casing 310 away from the frame 10. The supporting poles 313 are arranged in a line along a lengthwise direction of the frame 10. Each of the supporting poles 313 is substantially cylindrical. The supporting pole 313 prevents the display apparatus 100 rotating and decreases a loading weight on the hook portion 340. The casing 310 further defines two receiving holes 312 on the opposite side surfaces of the casing 310. The shaft 311 and the corresponding receiving hole 312 on the same side surface are symmetrically located. In at least embodiment, the casing 310 receives a main board and a power board. The casing 310 is made of metal.

The fixing portion 320 fixes the casing 310 on the back surface of the frame 10. The fixing portion 320 includes a main body 321. The main body 321 is substantially arched. The main body 321 defines a plurality of through holes 322 corresponding to the receiving portions 132 and a pivot hole 323. The through holes 322 are arranged on corners of the main body 321. The pivot hole 223 receives the shaft 213.

The movable leg 330 is capable of being mounted on the back surface of the frame 10 or being mounted on the casing 310. The movable leg 330 is substantially in an “L” shape. The movable leg 330 includes a connecting portion 331 and a resisting portion 332 perpendicular to the connecting portion 331. The connecting portion 331 is substantially cylindrical. The resisting portion 332 is substantially cuboid. The resisting portion 332 defines a groove 333 and a latching hole 334 located in the middle of the groove 333. In another embodiment, the resisting portion 332 can define a plurality of grooves 333 arranged in a line.

The hook portion 340 is substantially plate shaped. The hook portion 340 hooks onto the movable leg 330. The hook portion 340 defines at least two hanging holes 341 arranged in a line. The hanging holes 341 cooperate with the external structure via screws (not shown) for hanging the display apparatus 100 on a structure, such as a wall.

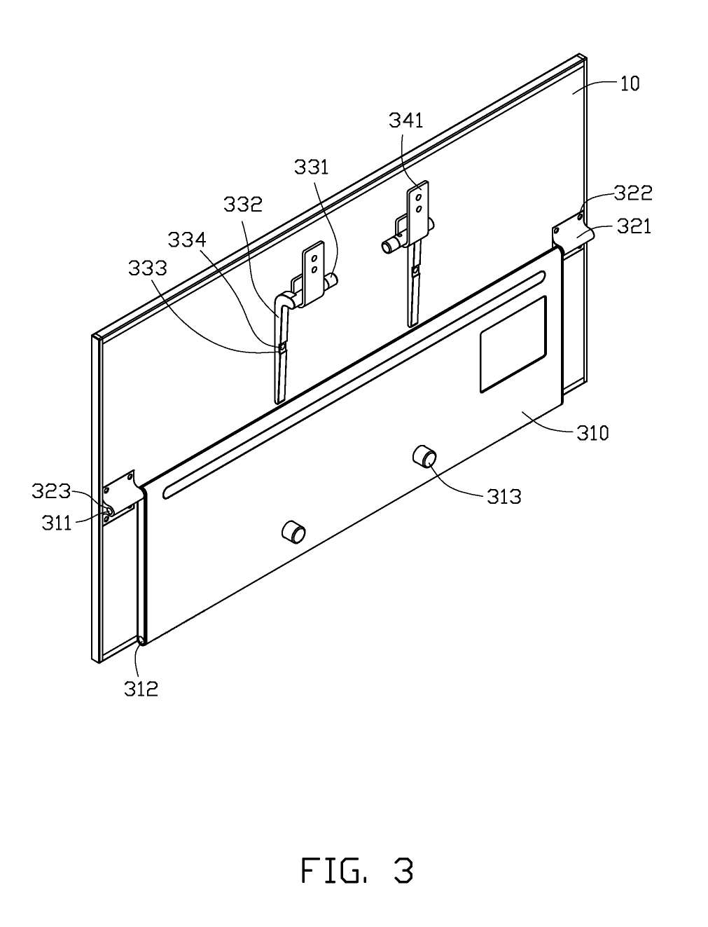

FIG. 3 illustrates the embodiment of the display apparatus 100 placed in the first placing orientation. The shaft 331 is rotatably received in the pivot hole 323. The fixing portion 320 cooperates with the positioning portion 110 via screws (not shown) to fix the casing 310 on the back surface of the frame 10. The casing 310 abuts the back surface of the frame 10. The connecting portions 331 face with each other. The latching hole 334 cooperates with the first opening 120 via a screw (not shown) to fix the movable legs 330 on the back surface of the frame 10. The hook portion 340 hooks up to the connecting portion 331, and the hanging hole 341 cooperates with the external structure via screws (not shown). Thus, the display apparatus 100 can be hung on the external structure.

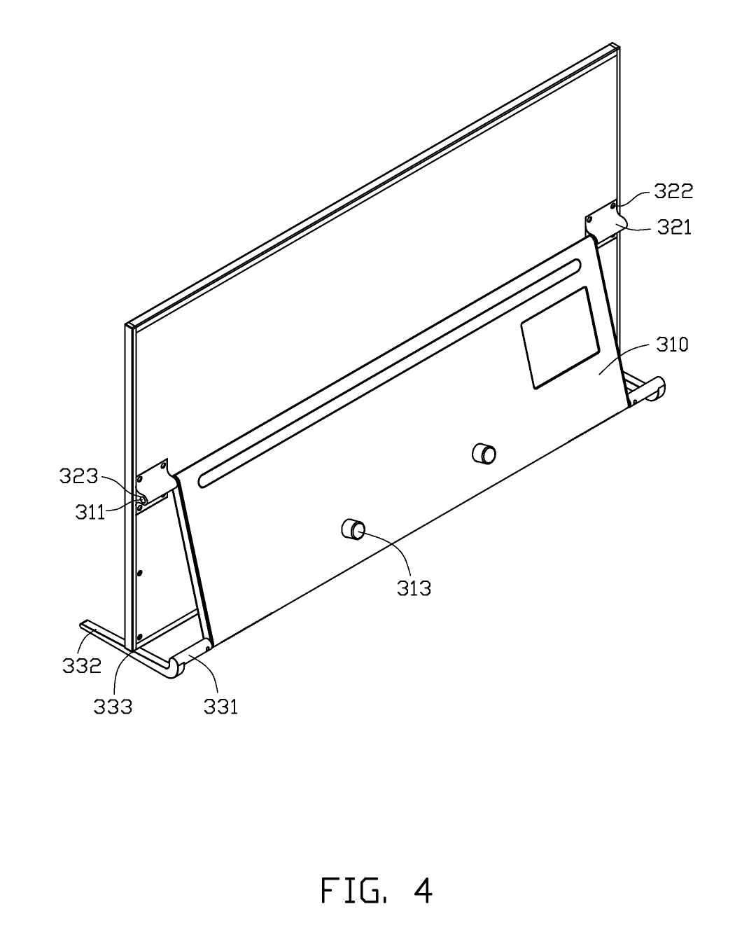

FIG. 4 illustrates the embodiment of the display apparatus 100 placed in the second placing orientation. The casing 310 rotates along the axis of the shaft 331 to make an angle with the frame 10. The movable leg 330 is disassembled from the first opening 120. An end of the connecting portion 331 away from the resisting portion 332 is inserted into the receiving hole 312. A bottom surface of the frame 10 is received in the groove 333. Thus, the frame 10, the movable leg 330, and the casing 310 form a triangle for supporting the display apparatus 100 on a flat structure, such as a table. In at least one embodiment, the casing 310 and the frame 10 form an acute angle.

In one embodiment, the shaft 311 is substantially cylindrical and hollow. The shaft 311 defines a gap facing the frame 10. The main body 321 further defines a second opening communicating with the pivot hole 323. A flexible flat cable (FFC) in the casing 310 passes through the shaft 311, the gap, the second opening, and the frame 10 in that order to electrically connect the display panel 20.

In use, mounting the movable leg 330 on different portions of the display apparatus 100 enables an orientation of placing the display apparatus 100 to be adjusted. While the orientation of placing of the display apparatus 100 is being changed, the main board and the power board of the casing 310 remain electrically connecting with the display panel 20. Therefore, a convenience of the display apparatus 100 is improved.

While various exemplary and preferred embodiments have been described, the disclosure is not limited thereto. On the contrary, various modifications and similar arrangements (as would be apparent to those skilled in the art) are intended to also be covered. Therefore, the scope of the appended claims should be accorded the broadest interpretation so as to encompass all such modifications and similar arrangements.

What is claimed is:

1. A display apparatus capable of being placed in different orientation, the display apparatus comprising:
a frame;
a display panel received in the frame, and configured to display images;
a casing rotatably mounted the frame via a fixing portion, the frame and casing being pivotal relative one another between a first display orientation and a second display orientation; and
at least one movable leg movable from a first position on the frame when the frame and casing are in the first display orientation to a second position to cooperate with the casing and frame to place the frame and casing in the second display orientation.

2. The display apparatus of claim 1, wherein the at least one movable leg comprises a resisting portion; the resisting portion defines at least one latching hole; the frame defines at least one first opening corresponding to the at least one latching hole; when the display apparatus in the first placing orientation, the at least one latching hole cooperates with the corresponding first opening to fix the at least one movable leg on a back surface of the frame, and the casing abuts the frame.

3. The display apparatus of claim 2, further comprising a hook portion; wherein the hook portion defines at least one hanging hole; the hook portion hooks up to the frame, and the hanging hole cooperates with an external structure for hanging the display apparatus on the external structure.

4. The display apparatus of claim 2, wherein the at least one movable leg further comprises a connecting portion perpendicular to the resisting portion; the resisting portion define a groove; the casing defines a receiving hole on a side surface of the casing; when the display apparatus is in the second placing orientation, the at least one movable leg is disassembled with the at least one first opening, the casing rotates to angle with the frame, an end of the connecting portion away from the resisting portion is inserted into the receiving hole, and a bottom surface of the frame is received in the groove; and the frame, the at least one movable leg, and the casing are arranged as a triangle shape.

5. The display apparatus of claim 4, wherein the casing and the frame form an acute angle.

6. The display apparatus of claim 4, wherein the latching hole is set on a bottom surface of the groove.

7. The display apparatus of claim 2, wherein the casing further comprises two positioning poles located on the back surface of the casing away from the display panel; the positioning poles are arranged in a line along a length direction of the frame; when the display apparatus in the first placing orientation, the supporting pole prevents the display apparatus to rotate.

8. The display apparatus of claim 1, wherein the casing further comprises a shaft mounted on the side surface of the casing; the fixing portion comprises a main body; the main body defines a pivot hole; the shaft is received in the pivot hole.

9. The display apparatus of claim 1, wherein the casing further integrates a main board for providing signals to the display panel, a power board for providing voltages, and at least one loudspeaker together.

10. A display apparatus comprising:
a frame;
a display panel received in the frame, and the display panel configured to display images;
a casing rotatably mounted to the frame via a fixing portion;
at least one movable leg; and
a hook portion;
wherein the at least movable leg is mounted on with the frame, the casing abuts the frame, the hook portion hooks up to the at least movable leg and cooperates with an external structure for hanging the display apparatus on the external structure.

11. The display apparatus of claim 10, wherein the at least one movable leg comprises a resisting portion; the resisting portion defines a latching hole; the frame defines at least one first opening corresponding to the latching hole; the latching hole cooperates with the first opening to fix the at least one movable legs on the back surface of the frame.

12. The display apparatus of claim 11, wherein the at least movable leg disassembled with the frame is located under the frame, the at least movable simultaneously cooperates with the casing and the frame to support the display apparatus on the external structure.

13. The display apparatus of claim 12, wherein the at least one movable leg further comprises a connecting portion perpendicular to the resisting portion; the resisting portion define a groove; the casing defines a receiving hole on a side surface of the casing; the at least one movable leg disassembled with the first opening is located under the frame, the casing rotates to angle with the frame, an end of the connecting portion away from the resisting portion is inserted into the receiving hole, and a bottom surface of the frame is received in the groove; the frame, the at least one movable leg, and the casing form a triangle for supporting the display apparatus on the external structure.

14. The display apparatus of claim 13, wherein the casing and the frame form an acute angle.

15. The display apparatus of claim 13, wherein the latching hole is set on the bottom surface of the groove.

16. The display apparatus of claim 10, wherein the casing further comprises two positioning poles located on the back surface of the casing away from the frame; the positioning poles are arranged in a line along a length direction of the frame; when the display apparatus being supported on the external device, the supporting pole prevents the display apparatus to rotate.

17. The display apparatus of claim 10, wherein the casing further comprises a shaft mounted on the side surface of the casing; the fixing portion comprises a main body; the main body defines a pivot hole; the shaft is received in the pivot hole.

18. The display apparatus of claim 10, wherein the casing further integrates a main board for providing signals to the display panel, a power board for providing voltages, and at least one loudspeaker together.
